(19) United States
(12) Patent Application Publication
(10) Pub. No.: US 2024/0291463 A1
(43) Pub. Date: Aug. 29, 2024

(54) ACOUSTIC WAVE DEVICE

(71) Applicant: Murata Manufacturing Co., Ltd., Nagaokakyo-shi (JP)

(72) Inventor: Yasunobu HAYASHI, Nagaokakyo-shi (JP)

(21) Appl. No.: 18/536,303

(22) Filed: Dec. 12, 2023

(30) Foreign Application Priority Data
Feb. 24, 2023 (JP) 2023-027192

(51) Int. Cl. H03H 9/02; H03H 3/08; H03H 9/25

(52) U.S. Cl. CPC H03H 9/02574; H03H 3/08; H03H 9/02661; H03H 9/25

(57) ABSTRACT

An acoustic wave device includes a piezoelectric substrate and an IDT electrode including an adhesive layer on the piezoelectric substrate, and an electrode layer on the adhesive layer. The electrode layer and the adhesive layer each include a metal element as a main material, and an additive. The additive in the electrode layer and the additive in the adhesive layer are of the same element.

### CROSS REFERENCE TO RELATED APPLICATIONS

This application claims the benefit of priority to Japanese Patent Application No. 2023-027192 filed on Feb. 24, 2023. The entire contents of this application are hereby incorporated herein by reference.

### BACKGROUND OF THE INVENTION

### 1. Field of the Invention

The present invention relates to an acoustic wave device.

### 2. Description of the Related Art

Acoustic wave devices have been widely used, for example, in filters for mobile phones. Japanese Unexamined Patent Application Publication No. 2006-115548 discloses an exemplary acoustic wave device. The acoustic wave device includes an IDT (Interdigital Transducer) electrode provided on a piezoelectric substrate. The IDT electrode includes an adhesive layer and a main electrode layer. The adhesive layer is provided between the piezoelectric substrate and the main electrode layer. The adhesive layer includes Ti as a main component. The main electrode layer is made of Cu or an alloy containing Cu as a main component.

### SUMMARY OF THE INVENTION

The acoustic wave device described in Japanese Unexamined Patent Application Publication No. 2006-115548 has the drawback that when electric power is applied to the IDT electrode, delamination may occur between the adhesive layer and the main electrode layer. This may result in a failure to achieve a sufficiently high power durability of the IDT electrode.

Preferred embodiments of the present invention provide acoustic wave devices which can each increase a power durability of an IDT electrode.

An acoustic wave device according to a preferred embodiment of the present invention includes a piezoelectric substrate, and an IDT electrode including an adhesive layer provided on the piezoelectric substrate, and an electrode layer provided on the adhesive layer, wherein the electrode layer and the adhesive layer each include a metal element as a main material, and an additive, and the additive in the electrode layer and the additive in the adhesive layer are a same element.

According to the acoustic wave devices of preferred embodiments of the present invention, it is possible to increase the power durability of an IDT electrode.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1 is an elevational cross-sectional view of an acoustic wave device according to a first preferred embodiment of the present invention.

FIG. 2 is a plan view of the acoustic wave device according to the first preferred embodiment of the present invention.

FIG. 3 is a schematic elevational cross-sectional view showing an electrode finger and its vicinity in the first preferred embodiment of the present invention.

FIG. 4 is an exemplary binary phase diagram for arbitrary elements X and Z.

### DETAILED DESCRIPTION OF THE PREFERRED EMBODIMENTS

Specific preferred embodiments of the present invention will now be described with reference to the drawings to clarify the present invention.

It should be noted that the preferred embodiments are illustrated by way of example, and that any partial replacement or combination will be possible between features of different preferred embodiments.

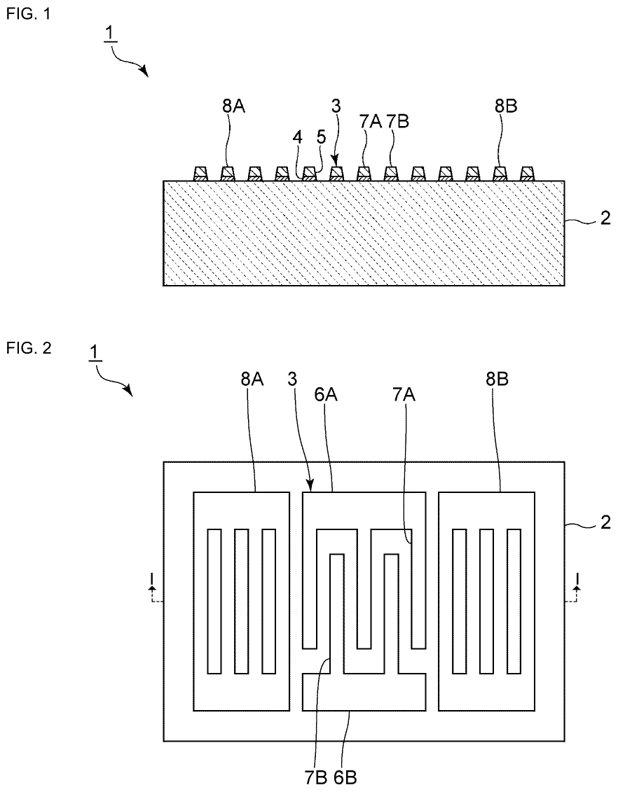

FIG. 1 is an elevational cross-sectional view of an acoustic wave device according to a first preferred embodiment of the present invention. FIG. 2 is a plan view of the acoustic wave device according to the first preferred embodiment. FIG. 1 is a cross-sectional view taken along line I-I in FIG. 2.

As shown in FIG. 1, the acoustic wave device 1 includes a piezoelectric substrate 2. In this preferred embodiment, the piezoelectric substrate 2 preferably is composed solely of a piezoelectric material, for example. Lithium tantalate, lithium niobate, zinc oxide, aluminum nitride, crystal, or PZT (lead zirconate titanate), for example, can be used as the piezoelectric material. The piezoelectric substrate 2 may be any substrate that has piezoelectricity. For example, the piezoelectric substrate 2 may be a laminated substrate including a piezoelectric layer.

An IDT electrode 3 is provided on the piezoelectric substrate 2. Acoustic waves are excited by applying an alternating current voltage to the IDT electrode 3. A pair of reflectors 8A and 8B are provided on the piezoelectric substrate 2 on both sides of the IDT electrode 3 in the direction of propagation of acoustic waves. The acoustic wave device 1 of this preferred embodiment is a surface acoustic wave resonator. It should be noted, however, that acoustic wave devices according to preferred embodiments of the present invention are not limited to acoustic wave resonators. For example, preferred embodiments of the present invention may be filter devices or multiplexers which each includes a plurality of acoustic wave resonators.

As shown in FIG. 2, the IDT electrode 3 includes a first busbar 6A, a second busbar 6B, a plurality of first electrode fingers 7A, and a plurality of second electrode fingers 7B. The first busbar 6A and the second busbar 6B are opposed to each other. One end of each first electrode finger 7A is connected to the first busbar 6A. One end of each second electrode finger 7B is connected to the second busbar 6B. The first electrode fingers 7A and the second electrode fingers 7B are interdigitated with each other.

The direction in which the first electrode fingers 7A and the second electrode fingers 7B extend is perpendicular or substantially perpendicular to the direction of propagation of acoustic waves. The first electrode fingers 7A and the second electrode fingers 7B hereinafter may be collectively referred to simply as the electrode fingers.

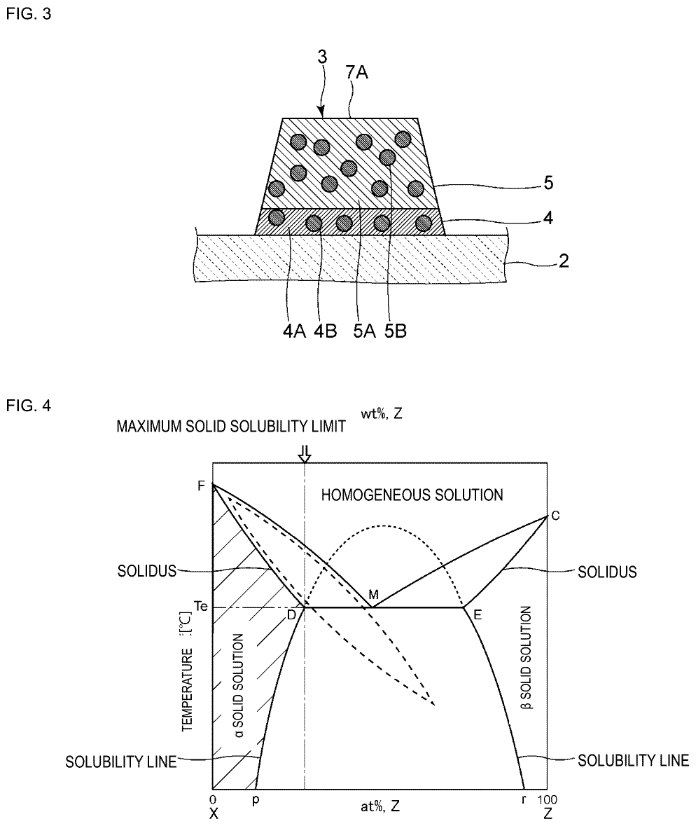

FIG. 3 is a schematic elevational cross-sectional view showing an electrode finger and its vicinity in the first preferred embodiment of the present invention. FIG. 3 shows one of the first electrode fingers 7A and its vicinity. Each second electrode finger 7B has the same construction as each first electrode finger 7A.

The IDT electrode 3 includes an adhesive layer 4 and an electrode layer 5 as a main electrode layer. The adhesive layer 4 is provided on the piezoelectric substrate 2. The electrode layer 5 is provided on the adhesive layer 4. More specifically, the electrode layer 5 is provided directly on the adhesive layer 4. The adhesive layer 4 includes a metal element as a main material 4A, and an element as an additive 4B. Similarly, the electrode layer 5 includes a metal element as a main material 5A, and an element as an additive 5B.

The main material of a member herein refers to an element whose atomic composition percentage in the member exceeds 50 at %. An element herein may sometimes be treated as having the same meaning as atoms of the electrode layer 5 or the adhesive layer 4. Thus, an element may sometimes be described as a collective entity of such atoms.

In the IDT electrode 3 of the acoustic wave device 1, the metal element as the main material 5A of the electrode layer 5 is Cu. The element as the additive 5B of the electrode layer 5 is Sn. The metal element as the main material 4A of the adhesive layer 4 is Ti. The element as the additive 4B of the adhesive layer 4 is Sn. However, the main material 5A and the additive 5B of the electrode layer 5, and the main material 4A and the additive 4B of the adhesive layer 4 are not limited to the above elements.

The electrode layer 5 may include the metal element as the main material 5A, the additive 5B, and an element other than the main material 5A and the additive 5B. The element and the main material 5A may define an alloy. However, it is not necessary that the entire main material 5A define the alloy. Thus, the electrode layer 5 may include the metal element as the main material 5A, the additive 5B, and the element other than the main material 5A and the additive 5B, and include the alloy including the element and the main material 5A. Similarly, the adhesive layer 4 may include the metal element as the main material 4A, the additive 4B, and an element other than the main material 4A and the additive 4B, and include an alloy including the element and the main material 4A.

This preferred embodiment is characterized in that the electrode layer 5 and the adhesive layer 4 each include a main material and an additive, and that the additive 5B of the electrode layer 5 and the additive 4B of the adhesive layer 4 are of the same element. This can increase the power durability of the IDT electrode 3.

A comparison of the power durability of IDT electrode was made between an acoustic wave device having the construction of the first preferred embodiment and a comparative acoustic wave device. The comparative device differs from the device according to the first preferred embodiment in that the electrode layer as a main electrode layer and the adhesive layer contain no additive. Examples of the acoustic wave device having the construction of the first preferred embodiment and the comparative acoustic wave device were prepared, and each device was subjected to a long-time power application test. As a result, the time it took for the IDT electrode according to the first preferred embodiment to break due to the application of electric power was about 2000 times longer than the time it took for the comparative IDT electrode to break due to the application of electric power. The acoustic wave device of the first preferred embodiment can thus increase the power durability of the IDT electrode.

Further, a failure analysis was performed on the acoustic wave device having the construction of the first preferred embodiment and on the comparative acoustic wave device. The comparative IDT electrode was damaged due to the occurrence of delamination between the electrode layer as a main electrode layer and the adhesive layer. On the other hand, in the IDT electrode according to the first preferred embodiment, no delamination occurred between the electrode layer as a main electrode layer and the adhesive layer despite the fact that the time until breakage of the IDT electrode was about 2000 times longer than that of the comparative IDT electrode. Breakage was observed in an adhesive layer-side portion of the electrode layer.

Since the first preferred embodiment shown in FIG. 3 can enhance the adhesion between the electrode layer 5 and the adhesive layer 4, breakage of the IDT electrode 3 due to delamination between the electrode layer 5 and the adhesive layer 4 can be made to be unlikely to occur, thereby increasing the power durability of the IDT electrode 3. This is because the electrode layer 5 and the adhesive layer 4 each include a main material and an additive, and the additive 5B of the electrode layer 5 and the additive 4B of the adhesive layer 4 are of the same element.

The IDT electrode 3 according to the first preferred embodiment can be formed, for example, by using a lift-off method. In particular, the piezoelectric substrate 2 is first prepared. Subsequently, a resist pattern is provided on the piezoelectric substrate 2. Subsequently, a metal layer for the main material 4A of the adhesive layer 4 is provided over the piezoelectric substrate 2 and the resist pattern. In the formation of the IDT electrode 3 according to the first preferred embodiment, a Ti layer is provided as the metal layer on the piezoelectric substrate 2. The metal layer can be formed, for example, by vacuum deposition or sputtering.

Next, an alloy layer, including a metal element as the main material 5A of the electrode layer 5 and an element as the additive 5B, is provided on the metal layer for the main material 4A of the adhesive layer 4. In the formation of the IDT electrode 3 according to the first preferred embodiment, a Cu—Sn alloy layer is provided as the alloy layer on the Ti layer. The alloy layer can be formed, for example, by alloy vapor deposition, binary vapor deposition, or sputtering.

Next, the resist pattern is peeled off to form an electrode pattern including a laminated metal film including the metal layer and the alloy layer. The electrode pattern is then heat-treated, for example at a temperature of not less than about 250° C. and not more than about 300° C. for about 4 hours. Through the heat treatment, the element as the additive 5B, contained in the alloy layer, diffuses into the metal layer. In the formation of the IDT electrode 3 according to the first preferred embodiment, Sn diffuses from the Cu—Sn alloy layer into the Ti layer. As a result, the same element Sn is included in the adhesive layer 4 and in the electrode layer 5. The IDT electrode 3 is thus obtained.

In the above example method, the IDT electrode 3 is formed using a lift-off method. Alternatively, the IDT electrode 3 may be formed, for example, by the following method. A laminated metal film including the metal layer and the alloy layer is first formed on the piezoelectric substrate 2, and then a resist pattern is formed on the laminated metal film. The substrate surface is then subjected to etching to form an electrode pattern, followed by peeling-off of the resist pattern. The electrode pattern is then subjected to heat treatment.

In the above-described example methods, the element as the additive 5B, included in the alloy layer for the electrode layer 5, is diffused into the metal layer for the main material 4A of the adhesive layer 4 by heat treatment, whereby the arrangement of atoms at the interface between the electrode layer 5 and the adhesive layer 4 can be made complex. This can effectively enhance the adhesion between the electrode layer 5 and the adhesive layer 4, thereby effectively increasing the power durability of the acoustic wave device 1.

Before forming the alloy layer for the electrode layer 5, an alloy layer may be formed which includes the main material 4A and the additive 4B of the adhesive layer 4. The alloy layer can be formed, for example, by alloy vapor deposition, binary vapor deposition, or sputtering. In this case, the above-described heat treatment is not essential but optional.

It is preferred that a metal element having high adhesion to the piezoelectric substrate 2 and to the electrode layer 5 be selected for the main material 4A of the adhesive layer 4. On the other hand, the additive 4B of the adhesive layer 4 can be selected regardless of such adhesion. Therefore, the degree of freedom in selecting the additive 5B of the electrode layer 5, which is the same element as the additive 4B, is also high. For example, the electrical resistance of the additive 5B is preferably lower than that of the main material 4A of the adhesive layer 4. This can securely reduce the electrical resistance of the IDT electrode 3. Even when a metal element having a low electrical resistance is selected as the main material 5A of the electrode layer 5 in order to improve the electrical characteristics of the acoustic wave device 1, it is possible to prevent the electrical resistance of the IDT electrode 3 from being high.

In the adhesive layer 4, the combination of the metal element as the main material 4A and the additive 4B is preferably a combination which can form a solid solution in which the additive 4B is dissolved in the main material 4A. More preferably, in the adhesive layer 4, the maximum solid solubility limit of the additive 4B in the main material 4A is about 5 wt % or more, for example. This can increase the strength of the adhesive layer 4, and therefore can effectively increase the power durability of the IDT electrode 3. The maximum solid solubility limit will now be described with reference to FIG. 4.

FIG. 4 shows an exemplary binary phase diagram for arbitrary elements X and Z. The a solid solution in FIG. 4 is a solid solution in which the element Z is dissolved in the element X. The β solid solution is a solid solution in which the element X is dissolved in the element Z. In FIG. 4, the range in which the elements X and Z are present in the state of the a solid solution is indicated by hatching. The lower horizontal axis in FIG. 4 represents the atomic composition percentage of the element Z. The upper horizontal axis represents the weight percent concentration of the element Z.

Point C in FIG. 4 indicates the boundary between the solid state and the liquid state when the concentration of the element Z is 100 at %. The temperature at point C is the melting point of the element Z. Point F indicates the boundary between the solid state and the liquid state when the concentration of the element Z is 0 at % and the concentration of the element X is 100 at %. The temperature at point F is the melting point of the element X. Point D and point E are each the intersection of the solubility line and the solidus. Point M is a eutectic point. The temperature at point D, point E and point M corresponds to the eutectic temperature Te.

In the first preferred embodiment shown in FIG. 3, the element X in FIG. 4 corresponds to the metal element as the main material 4A of the adhesive layer 4. The element Z corresponds to the element as the additive 4B of the adhesive layer 4. The a solid solution corresponds to a solid solution in which the additive 4B is dissolved in the main material 4A. The maximum solid solubility limit of the additive 4B in the main material 4A corresponds to the weight percent concentration at point D in FIG. 4. The maximum solid solubility limit may also be expressed in terms of atomic composition percentage.

The following are examples of preferred combinations of the metal element as the main material 4A of the adhesive layer 4 and the element as the additive 4B.

It is preferred that the metal element as the main material 4A of the adhesive layer 4 be Ti, and the additive 4B be one of Ag, Al, Nb, Sn, Ta, V, or Zr. In this case, the maximum solid solubility limit of the additive 4B in the main material 4A can be made to be about 5 wt % or more, for example. Therefore, the power durability of the IDT electrode 3 can be effectively increased.

It is preferred that the metal element as the main material 4A of the adhesive layer 4 be Ni, and the additive 4B be one of Al, Au, Cu, Cr, Fe, Ga, Mn, Nb, Si, Sn, Ta, or Zn. Such a combination can cause the maximum solid solubility limit of the additive 4B in the main material 4A to be about 5 wt % or more, for example. Therefore, the power durability of the IDT electrode 3 can be effectively increased.

Besides Ni, which is the main material 4A, and the additive 4B, the adhesive layer 4 may also include, for example, element P. Further, a Ni—P alloy may be included in the adhesive layer 4. Thus, the adhesive layer 4 may include Ni as the main material 4A, the additive 4B, and P, and include a Ni—P alloy. Alternatively, for example, the adhesive layer 4 may include Ni as the main material 4A, the additive 4B, and Cr, and include a Ni—Cr alloy, and the additive 4B may be one of Al, Au, Cu, Fe, Ga, Mn, Nb, Si, Sn, Ta, or Zn. Also in these cases, the power durability of the IDT electrode 3 can be effectively increased.

It is preferred that the metal element as the main material 4A of the adhesive layer 4 be Cr, and the element as the additive 4B be one of Al, Au, Ce, Co, Fe, Ga, Mn, Mo, Nb, Ni, Si, Sn, Ta, Ti, V, or W. In this case, the maximum solid solubility limit of the additive 4B in the main material 4A can be made to be about 5 wt % or more, for example. Therefore, the power durability of the IDT electrode 3 can be effectively increased.

The use of Cu as a material for an IDT electrode in the conventional acoustic wave device can improve the electrical characteristics of the device. However, the conventional device sometimes cannot achieve a sufficiently high power durability. In contrast, a sufficiently high power durability can be achieved according to the first preferred embodiment shown in FIG. 3 even when the main material 5A of the electrode layer 5 as a main electrode layer includes Cu as a main component. In view of this, the main material 5A is preferably Cu. Preferred embodiments of the present invention are particularly advantageous in this case. The electrode layer 5 may include Cu as the main material 5A, the additive 5B, and an element other than Cu and the additive 5B, and include an alloy including the element and Cu.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device comprising:
a piezoelectric substrate; and
an IDT electrode including an adhesive layer provided on the piezoelectric substrate, and an electrode layer provided on the adhesive layer; wherein
the electrode layer and the adhesive layer each include a metal element as a main material, and an additive; and
the additive in the electrode layer and the additive in the adhesive layer are a same element.

2. The acoustic wave device according to claim 1, wherein the metal element and the additive in the adhesive layer combine to define a solid solution in which the additive is dissolved in the main material such that a maximum solid solubility limit of the additive in the main material is about 5 wt % or more.

3. The acoustic wave device according to claim 1, wherein the metal element of the adhesive layer is Ti, and the additive is one of Ag, Al, Nb, Sn, Ta, V, or Zr.

4. The acoustic wave device according to claim 1, wherein the metal element of the adhesive layer is Ni, and the additive is one of Al, Au, Cu, Cr, Fe, Ga, Mn, Nb, Si, Sn, Ta, or Zn.

5. The acoustic wave device according to claim 1, wherein the metal element of the adhesive layer is Cr, and the additive is one of Al, Au, Ce, Co, Fe, Ga, Mn, Mo, Nb, Ni, Si, Sn, Ta, Ti, V, or W.

6. The acoustic wave device according to claim 1, wherein the metal element of the electrode layer is Cu.

7. The acoustic wave device according to claim 1, wherein the piezoelectric substrate includes only piezoelectric material.

8. The acoustic wave device according to claim 1, wherein the piezoelectric substrate is a laminated substrate including a piezoelectric layer.

9. The acoustic wave device according to claim 1, further comprising reflectors on both sides of the IDS electrode.

10. The acoustic wave device according to claim 1, wherein the acoustic wave device is an acoustic wave resonator.

11. The acoustic wave device according to claim 1, wherein the acoustic wave device is a filter device.

12. The acoustic wave device according to claim 1, wherein the acoustic wave device is a multiplexer.

13. The acoustic wave device according to claim 1, wherein the additive in the electrode layer and the additive in the adhesive layer are Sn.

14. The acoustic wave device according to claim 13, wherein the metal element of the electrode layer is Cu and the metal element of the adhesive layer is Ti.

15. The acoustic wave device according to claim 1, wherein the metal element and the additive of the electrode layer define an alloy.

16. The acoustic wave device according to claim 1, wherein the metal element and the additive of the adhesive layer define an alloy.

17. The acoustic wave device according to claim 1, wherein the adhesive layer includes P.

18. The acoustic wave device according to claim 1, wherein the adhesive layer includes an Ni—P alloy.

19. The acoustic wave device according to claim 1, wherein the metal element of the adhesive layer is Ni, and the adhesive layer also includes Cr.

20. The acoustic wave device according to claim 1, wherein the adhesive layer includes an Ni—Cr alloy.
